(19) United States
(12) Patent Application Publication
(10) Pub. No.: US 2017/0077395 A1
(43) Pub. Date: Mar. 16, 2017

(54) SEMICONDUCTOR DEVICES AND METHODS OF MANUFACTURING THE SAME

(71) Applicants: Yoonsung HAN, Seoul (KR); JONGCHUL PARK, Seongnam-si (KR)

(72) Inventors: Yoonsung HAN, Seoul (KR); JONGCHUL PARK, Seongnam-si (KR)

(21) Appl. No.: 15/214,447

(22) Filed: Jul. 19, 2016

(30) Foreign Application Priority Data
Sep. 11, 2015 (KR) 10-2015-0128903

(51) Int. Cl. H01L 43/12; H01L 27/22; H01L 43/10; H01L 43/02; H01L 43/08

(52) U.S. Cl. CPC H01L 43/12; H01L 43/02; H01L 43/08; H01L 43/10; H01L 27/228

(57) ABSTRACT

A semiconductor device includes a magnetic tunnel junction structure including a first magnetic pattern, a tunnel barrier pattern, and a second magnetic pattern that are disposed on a substrate. A material layer including oxidation-facilitation dopants is formed on a surface of the magnetic tunnel junction structure. The material layer is oxidized to be changed into an oxide layer.

### CROSS-REFERENCE TO RELATED APPLICATION

This application claims priority under 35 U.S.C. §119 to Korean Patent Application No. 10-2015-0128903 filed on Sep. 11, 2015, the entire contents of which are hereby incorporated by reference.

### BACKGROUND

Example embodiments of the inventive concepts relate to semiconductor devices and methods of manufacturing the same and, more particularly, to magnetic memory devices and methods for manufacturing the same.

To facilitate high-speed and low-power consumption electronic devices, semiconductor memory devices in the electronic devices are required to have rapid read/write performance and low operation voltages. Magnetic memory devices are being considered as semiconductor memory devices that may satisfy these requirements. Because magnetic memory devices generally have high-speed performance and/or non-volatile characteristics, they have drawn attention as being a next generation memory. Accordingly, based on the small size of the electronic devices, a high integration of the magnetic memory devices will be required.

### SUMMARY

According to example embodiments of the inventive concepts. a method of manufacturing a semiconductor device may include sequentially forming a first magnetic layer, a tunnel barrier layer, and a second magnetic layer on a substrate, forming a magnetic tunnel junction structure including a first magnetic pattern, a tunnel barrier pattern, and a second magnetic pattern that are sequentially stacked by etching the second magnetic layer, the tunnel barrier layer, and the first magnetic layer, forming a material layer including oxidation-facilitation dopants on a sidewall of the magnetic tunnel junction structure, and oxidizing the material layer to form an oxide layer.

According to example embodiments of the inventive concepts, a method of manufacturing a semiconductor device may include forming a selection device on a substrate, sequentially forming a bottom electrode layer, a first magnetic layer, a tunnel barrier layer, a second magnetic layer, a top electrode layer, on the substrate, forming a magnetic tunnel junction structure by etching the top electrode layer, the second magnetic layer, the tunnel barrier layer, the first magnetic layer, the bottom electrode layer. The magnetic tunnel junction structure may include a bottom electrode, a first magnetic pattern, the tunnel barrier pattern, a second magnetic pattern, and a top electrode that are sequentially stacked. The method may include forming a material layer including an oxidation-facilitation dopant on a sidewall of the magnetic tunnel junction structure and oxidizing the material layer.

According to example embodiments of the inventive concept, a method of manufacturing a semiconductor device may include forming a magnetic tunnel junction structure including a bottom electrode, a top electrode, and a magnetic tunnel junction between the bottom electrode and the top electrode. The magnetic tunnel junction may include a first magnetic pattern, a second magnetic pattern, and a magnetic tunnel barrier pattern between the first magnetic pattern and the second magnetic pattern. The method may include forming an oxide layer on a sidewall of the magnetic tunnel junction structure. The oxide layer may include oxygen, a metal, and at least one of boron and carbon.

According to example embodiments of the inventive concepts, a semiconductor device may include a magnetic tunnel junction structure including a bottom electrode, a top electrode, and a magnetic tunnel junction between the bottom electrode and the top electrode. The magnetic tunnel junction may include a first magnetic pattern, a second magnetic pattern, and a magnetic tunnel barrier pattern between the first magnetic pattern and the second magnetic pattern. The device may include an oxide layer including a metal, oxygen, and at least one of boron and carbon on a sidewall of the magnetic tunnel junction structure.

According to example embodiments, a method of manufacturing a semiconductor device may include forming a magnetic tunnel junction structure on a surface of a substrate in which the magnetic tunnel junction structure may comprise a bottom electrode layer, a first magnetic layer, a tunnel barrier layer, a second magnetic layer, and a top electrode layer sequentially formed on the surface of the substrate; etching the magnetic tunnel junction structure to form at least one magnetic tunnel junction device in which the at least one magnetic tunnel junction device may comprise a sidewall surface on which an etching by-product is attached; and forming an oxide layer from the etching by-product. The oxide may comprise oxygen, a metal and at least one of boron and carbon. The etching by-product may further be on the surface of the substrate, and forming an oxide layer may further comprise forming an oxide layer from the etching by-product on the surface of the substrate.

According to example embodiments, a semiconductor device may include at least one magnetic tunnel junction device on surface of a substrate in which the at least one magnetic tunnel junction device may comprise a bottom electrode, a first magnetic layer, a tunnel barrier layer, a second magnetic layer, and a top electrode sequentially formed on the surface of the substrate and in which the at least one magnetic tunnel junction device may comprises a sidewall surface; and an oxide layer on the sidewall surface of the at least one magnetic tunnel junction device in which the oxide layer may comprise a metal, oxygen, and at least one of boron and carbon. The oxide layer may further be on the surface of the substrate, and a capping layer may be on the oxide layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 depicts a block diagram of a magnetic memory device according to example embodiments of the inventive concepts.

FIG. 2 depicts a circuit diagram of a memory cell array of a magnetic memory device according to example embodiments of the inventive concepts.

FIGS. 3 through 7 are cross-sectional views depicting a method of manufacturing a magnetic tunnel junction structure of a magnetic memory device according to example embodiments of the inventive concepts.

FIG. 8 is a cross-sectional view depicting an oxidation process of the magnetic tunnel junction structure according to example embodiments of the inventive concepts.

FIG. 9 is a flow diagram of a method of manufacturing a magnetic tunnel junction structure corresponding to FIGS. 3 through 7 according to example embodiments of the inventive concepts.

FIG. 10 is a plan view depicting a semiconductor device according to example embodiments of the inventive concepts.

FIG. 11 is a cross-sectional view taken along line I-I′ of FIG. 10 to depict a semiconductor device according to example embodiments of the inventive concepts.

FIG. 12 is a cross-sectional view taken along line II-II′ of FIG. 10 to depict a semiconductor device according to example embodiments of the inventive concepts.

FIGS. 13A through 13D are enlarged cross-sectional views respectively depicting a magnetic tunnel junction structure according to example embodiments of the inventive concepts.

FIGS. 14 through 17 are cross-sectional views depicting a method of manufacturing a semiconductor device according to example embodiments of the inventive concepts.

FIG. 18 depicts an electronic device that comprises one or more integrated circuits (chips) comprising a magnetic tunnel junction device in accordance with example embodiments.

FIG. 19 depicts a memory system that may comprise one or more integrated circuits (chips) comprising a semiconductor device that includes a magnetic tunnel junction device in accordance with example embodiments.

### DETAILED DESCRIPTION

Example embodiments of the inventive concepts will now be described more fully with reference to the accompanying drawings, in which example embodiments are shown.

Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions may be exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first,” “second,” etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

As should be appreciated, devices and methods of forming devices according to various embodiments described herein may be embodied in microelectronic devices, such as integrated circuits, wherein a plurality of devices according to various embodiments described herein are integrated in the same microelectronic device. Accordingly, the cross-sectional view(s) depicted herein may be replicated in two different directions, which need not be orthogonal in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions to provide three-dimensional integrated circuits.

Accordingly, the cross-sectional view(s) depicted herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be depicted by a plan view of the device/structure.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, descriptions to example embodiments of the inventive concepts will be made with reference to drawings.

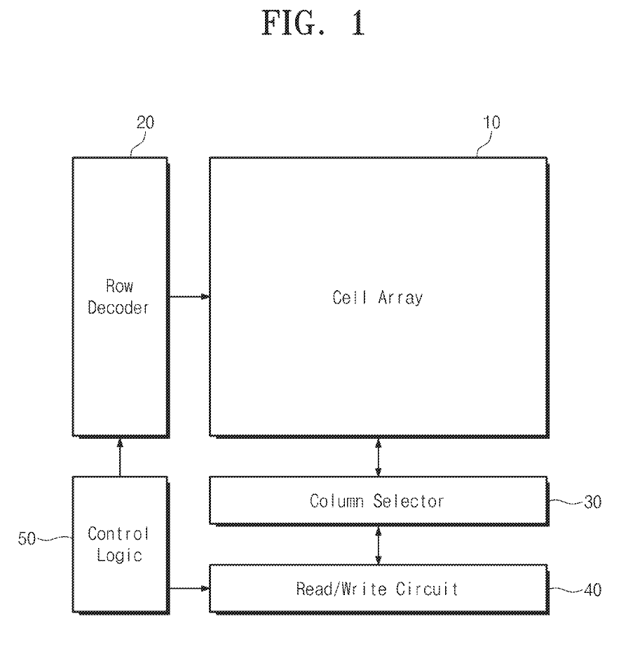

FIG. 1 depicts a block diagram of a magnetic memory device according to example embodiments of the inventive concepts.

Referring to FIG. 1, a magnetic memory device may include a memory cell array 10, a row decoder 20, a column selector 30, a read/write circuit 40, and a control logic 50.

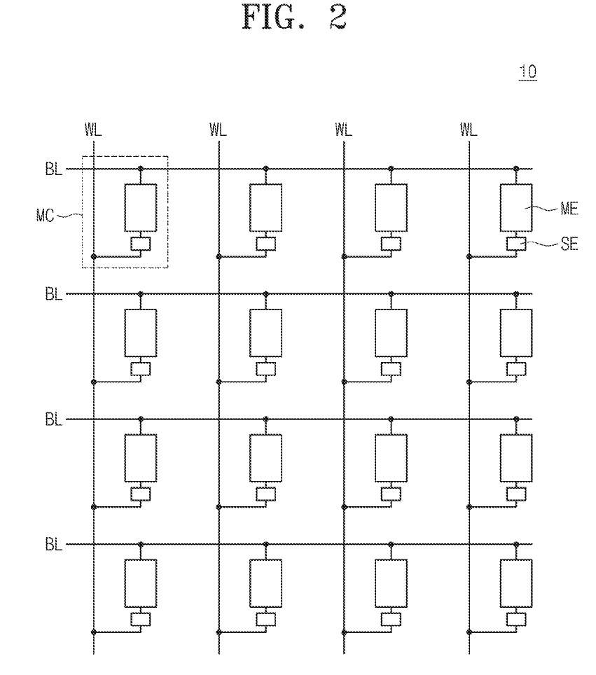

The memory cell array 10 may include a plurality of word lines, a plurality of bit lines, and a plurality of memory cells that are connected at respective crossing points between the word lines and the bit lines. The configuration of the memory cell array 10 will be described later with reference with FIG. 2.

The row decoder 20 may be connected to the memory cell array 10 via the word lines, and may decode an address signal received from outside the magnetic memory device to select one of the word lines.

The column selector 30 may be connected to the memory cell array 10 via the bit lines, and may decode an address signal inputted from outside the magnetic memory device to select one of the bit lines. The bit line selected by the column selector 30 may be connected to the read/write circuit 40.

The read/write circuit 40 may provide a bit line bias to access a memory cell selected by a control of the control logic 50. The read/write circuit 40 may provide a bit line voltage to a selected bit line to write input data in the memory cell or read input data.

The control logic 50 may output control signals to control the magnetic memory device according to a command signal provided from outside the magnetic memory device. The signals output from the control logic 50 may control the read/write circuit 40.

FIG. 2 depicts a circuit diagram of a memory cell array 10 of a magnetic memory device according to example embodiments of the inventive concepts.

Referring to FIG. 2, the memory cell array 10 may include a plurality of first conductive lines, a plurality of second conductive lines, and a plurality of unit memory cells MC. The first conductive lines may be word lines WL, and the second conductive lines may be bit lines BL. The unit memory cells MC may be configured to be connected at respective crossing points between the word lines WL and the bit lines BL. The unit memory cells MC may be arranged in two-dimensions or three-dimensions. For example, each of the word lines WL may be connected to a plurality of the unit memory cells MC that are arranged along the respective word line WL. Each of the bit lines BL may be connected to a plurality of unit memory cells MC that are arranged along the respective bit line BL. Thus, each of the unit memory cells MC—may be connected to a corresponding word line WL and may be connected to the read/write circuit 40 of FIG. 1 via a corresponding bit line BL.

Each of the unit memory cells MC may include a memory element ME and a selection device SE. The memory element ME may be configured to be connected between a bit line BL and the selection device SE. The selection device SE may be configured to be connected between the memory element ME and a word line WL. The memory element ME may be a variable resistive element that can switch between two resistive states depending on electrical pluses that are applied to the memory element ME.

In some example embodiments, the memory element ME may be configured to have a thin-film structure in which an electrical resistance of the thin-film structure can vary based on a spin transfer torque of a current flowing through the thin-film element. The memory element ME may be have a thin-film structure that is configured to exhibit magnetoresistance characteristics, and may include at least a ferromagnetic material and/or at least an anti-ferromagnetic material. For example, the memory element ME may be a magnetic memory element that includes a magnetic tunnel junction (MTJ).

The selection device SE may be configured to selectively control a flow of electric charges passing (i.e., a current) through the memory element ME. For example, the selection device SE may be a diode, a bipolar transistor, an NMOS field effect transistor or a PMOS field effect transistor. In some example embodiments, in the case in which the selection device SE is configured as a bipolar transistor or as a MOS field effect transistor, which has three nodes, an additional interconnection line not shown in FIG. 2 may be connected to the selection device SE.

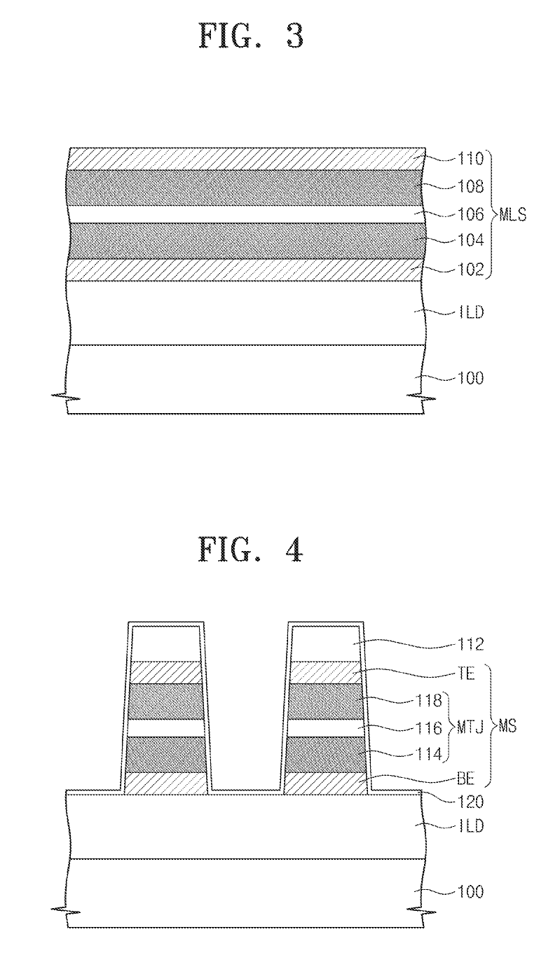

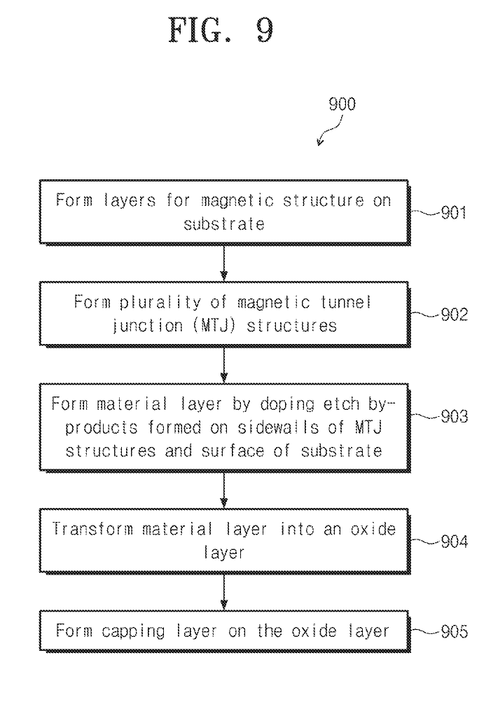

FIGS. 3 through 7 are cross-sectional views depicting a method of manufacturing a magnetic tunnel junction structure according to example embodiments of the inventive concepts. FIG. 9 is a flow diagram 900 of a method of manufacturing a magnetic tunnel junction structure corresponding to FIGS. 3 through 7 according to example embodiments of the inventive concepts.

Referring to FIG. 3 and operation 901 in FIG. 9, a magnetic structure MLS may be formed on a substrate 100 having a structure formed between the magnetic structure MLS and the substrate 100. As an example embodiment, the magnetic structure MLS may include a bottom electrode layer 102, a first magnetic layer 104, a tunnel barrier layer 106, a second magnetic layer 108, and a top electrode layer 110 that are sequentially stacked from the substrate 100.

The substrate 100 may be a semiconductor substrate that includes at least one of a silicon (Si) substrate, a germanium (Ge) substrate and a silicon germanium (SiGe) substrate.

In some example embodiments, the substrate 100 may include a conductive layer or conductive structure in the substrate 100.

The structure between the substrate 100 and the magnetic structure MLS may include an insulating layer ILD, such as a silicon oxide layer. Further, although not depicted, a contact plug may be formed within the insulating layer ILD such that the contact plug may be electrically connected to the conductive layer (not shown) or the conductive structure (not shown) in the substrate 100.

The bottom and top electrode layers 102 and 110 may each include a conductive metallic nitride (e.g., titanium nitride, tantalum nitride, and/or tungsten nitride), a transition metal (e.g., titanium and/or tantalum), and/or a precious metal (e.g., ruthenium and/or platinum).

One of the first magnetic layer 104 and the second magnetic layer 108 may be a layer that functions as a free magnetic layer of a magnetic tunnel junction that will be described later. The other layer of the first magnetic layer 104 and the second magnetic layer 108 may be a layer that functions as a pinned magnetic layer of the magnetic tunnel junction. For example, the first magnetic layer 104 may be a layer that functions as the pinned magnetic layer, and the second magnetic layer 108 may be a layer that functions as the free magnetic layer. Alternatively, the first magnetic layer 104 may be a layer that functions as the free magnetic layer, and the second magnetic layer 108 may be a layer that functions as the pinned magnetic layer.

In some example embodiments, the first and second magnetic layers 104 and 108 may be magnetic layers that form a horizontal magnetization structure in which a magnetization direction thereof is substantially parallel to a top surface of the tunnel barrier layer 106. That is, the first and second magnetic layers 104 and 108 may be magnetic layers that have a horizontal magnetic anisotropy. In this case, the first magnetic layer 104 may include a layer containing an anti-ferromagnetic material and a layer containing a ferromagnetic material. The layer containing anti-ferromagnetic material may include, for example, PtMn, IrMn, MnO, MnS, MnTe, MnF₂, FeCl₂, FeO, CoCl₂, CoO, NiCl₂, NiO and/or Cr. In some example embodiments, the layer containing anti-ferromagnetic material may include a precious metal, such as, ruthenium, rhodium, palladium, osmium, iridium, platinum, gold, and/or silver. The layer containing a ferromagnetic material may include, for example, CoFeB, Fe, Co, Ni, Gd, Dy, CoFe, CoFePt, CoFePd, CoFeCr, CoFeTb, CoFeGd, CoFeNi, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂.

The second magnetic layer 108 may include a material having a variable magnetization direction. That is, the second magnetic layer 108 may be a free magnetic layer based on the material forming the second magnetic layer 108. The second magnetic layer 108 may include a ferromagnetic material, for example, CoFeB, Fe, Co, Ni, Gd, Dy, CoFe, CoFePt, CoFePd, CoFeCr, CoFeTb, CoFeGd, CoFeNi, NiFe, MnAs, MnBi, MnSb, CrO₂, MnOFe₂O₃, FeOFe₂O₃, NiOFe₂O₃, CuOFe₂O₃, MgOFe₂O₃, EuO, and/or Y₃Fe₅O₁₂. In one embodiment, the second magnetic layer 108 may include a plurality of magnetic layers. For example, the second magnetic layer 108 may include a plurality of layers containing a ferromagnetic material and a layer containing a nonmagnetic material interposed between adjacent layers containing the ferromagnetic material. In this case, the layer containing the nonmagnetic material and the adjacent layers containing the ferromagnetic material may form a synthetic antiferromagnetic layer. The synthetic antiferromagnetic layer may reduce a critical current density of the magnetic memory element and may also improve thermal stability.

In other example embodiments, the first and second magnetic layers 104 and 108 may be magnetic layers that form a vertical magnetization structure in which a magnetization direction thereof is substantially perpendicular to the top surface of the tunnel barrier layer 106. That is, the first and second magnetic layers 104 and 108 may be magnetic layers having a vertical magnetic anisotropy. In this case, the first and second magnetic layers 104 and 108 may include a vertical magnetization material (e.g., CoFeTb, CoFeGd, and/or CoFeDy), a material having a crystal structure of L1₀, a material having a hexagonal close packed (HCP) lattice, and/or a material having an amorphous rare-earth transition metal (RE-TM). For example, the first and second magnetic layers 104 and 108 may include a material having the crystal structure of L1₀, for example, Fe₅₀Pt₅₀, Fe₅₀Pd₅₀, Co₅₀Pt₅₀, Co₅₀Pd₅₀, and/or Fe₅₀Ni₅₀. The first and second magnetic layers 104 and 108 may include, for example, a disordered cobalt-platinum alloy (CoPt) or an ordered cobalt-platinum alloy (Co₃Pt), each of which may have a concentration of platinum ranging from 10 at % to 45 at % and has the hexagonal close packed lattice. The first and second magnetic layers 104 and 108 may include an amorphous RE-TM including, for example, at least one of iron (Fe) and nickel (Ni), and, for example, at least one of terbium, dysprosium (Dy) and gadolinium (Gd), each of which is a rare earth metal.

The first and second magnetic layers 104 and 108 may include a material having an interface perpendicular magnetic anisotropy. As used herein, an interface perpendicular magnetic anisotropy means a phenomenon in which a magnetic layer having an inherent horizontal magnetization characteristic is changed to have a vertical magnetization characteristic by an influence from an interface between the magnetic layer and another magnetic layer that is adjacent to the magnetic layer. As used herein, an inherent horizontal magnetization characteristic mean that a magnetic layer has a magnetization direction parallel to the largest surface thereof when no outside factors (or influences) are present. For example, when a magnetic layer having an inherent horizontal magnetization characteristic may be formed on the substrate 100, the magnetization direction of the magnetic layer may be substantially parallel to a top surface of the substrate 100 in the case in which there are no outside factors.

As an example embodiment, the first and second magnetic layers 104 and 108 may include cobalt (Co), iron (Fe) and/or nickel (Ni). The first and second magnetic layers 104 and 108 may further include at least one nonmagnetic material including, for example, boron (B), zinc (Zn), aluminum (Al), titanium (Ti), ruthenium (Ru). tantalum (Ta), silicon (Si), silver (Ag), gold (Au), copper (Cu), carbon (C) and/or nitrogen (N). For example, the first and second magnetic layers 104 and 108 may include CoFe and/or NiFe, and may further include boron. Additionally, the first and second magnetic layers 104 and 108 may further include titanium (Ti), aluminum (Al), silicon (Si), magnesium (Mg) and/or tantalum (Ta) to lower an amount of saturated magnetization of each of the first and second magnetic layers 104 and 108. The first and second magnetic layers 104 and 108 may be formed using a sputtering process or a plasma enhanced chemical vapor deposition (PECVD) process.

The tunnel barrier layer 106 may include magnesium oxide (MgO). titanium oxide (TiO), aluminum oxide (AlO), magnesium-zinc oxide (MgZnO), magnesium-boron oxide (MgBO), titanium nitride (TiN), and/or vanadium nitride (VN). For example, the tunnel barrier layer 106 may be a single layer including magnesium oxide (MgO). In some example embodiments, the tunnel barrier layer 106 may include multiple layers.

Referring to FIG. 4 and operation 902 in FIG. 9, a plurality of magnetic tunnel junction structures MS may be formed by patterning the magnetic structure MLS of FIG. 3. The patterning process of the magnetic structure MLS may include forming a mask pattern 112 on the top electrode layer 110 of FIG. 3, and performing an etching process of the magnetic structure MLS using the mask pattern 112 as an etch mask. For example, a bottom electrode layer 102, a first magnetic layer 104, a tunnel barrier layer 106, a second magnetic layer 108, and a top electrode layer 110 may be patterned using the mask pattern 112 as an etch mask. The mask pattern 112 may include silicon oxide, silicon nitride and/or silicon oxynitride.

Each of the magnetic tunnel junction structures MS formed by the etching process may include a bottom electrode BE, a first magnetic pattern 114, a tunnel barrier pattern 116, a second magnetic pattern 118 and a top electrode TE. The first magnetic pattern 114, the tunnel barrier pattern 116, and the second magnetic pattern 118 may form a magnetic tunnel junction (MTJ). The etching process of the magnetic structure MLS may include an ion sputtering process and/or a reactive ion etching process.

When the magnetic structure MLS is patterned, etch by-products 120 may be produced, as depicted in FIG. 4. Since the magnetic structure MLS includes a metal, such as Pt, Pd, Co, Mg, Fe, and/or a precious metal other than palladium (Pd), an etching speed during the etching process for forming the magnetic tunnel junction structures MS may be slower than the etching speed during an etching process of an insulating layer or of a silicon layer, thereby generating the etch by-products 120. Further, the etch by-products 120 may have a saturation vapor pressure that is lower than a saturation vapor pressure of etch by-products that are produced during etching of a nonmetallic material, such as silicon or silicon oxide. As a result, the etch by-products 120 may remain on sidewalls of the magnetic tunnel junction structures MS, such that a large amount of conductive etch by-products 120 may be formed on the sidewalls of the magnetic tunnel junction structures MS. Although the etch by-products 120 may be formed to be uniform and continuous on substrate 100 on which the magnetic tunnel junction structures MS are formed, as depicted in the drawings, the etch by-products 120 may have a random thickness and/or configuration. When the conductive etch by-products 120 are attached on sidewalls of the tunnel barrier pattern 116, a short circuit may be formed between the first magnetic pattern 114 and the second magnetic pattern 118 during operation of the memory cell. When conductive etch by-products 120 remain between adjacent magnetic tunnel junction structures MS., an undesired electrical connection between the adjacent magnetic tunnel junction structure MS also may be formed. As a distance between adjacent magnetic tunnel junction structures MS is reduced to 100 nm or less based on integration scaling of the magnetic memory device, occurrence of undesired electrical connections between adjacent magnetic tunnel junction structures MS may increase.

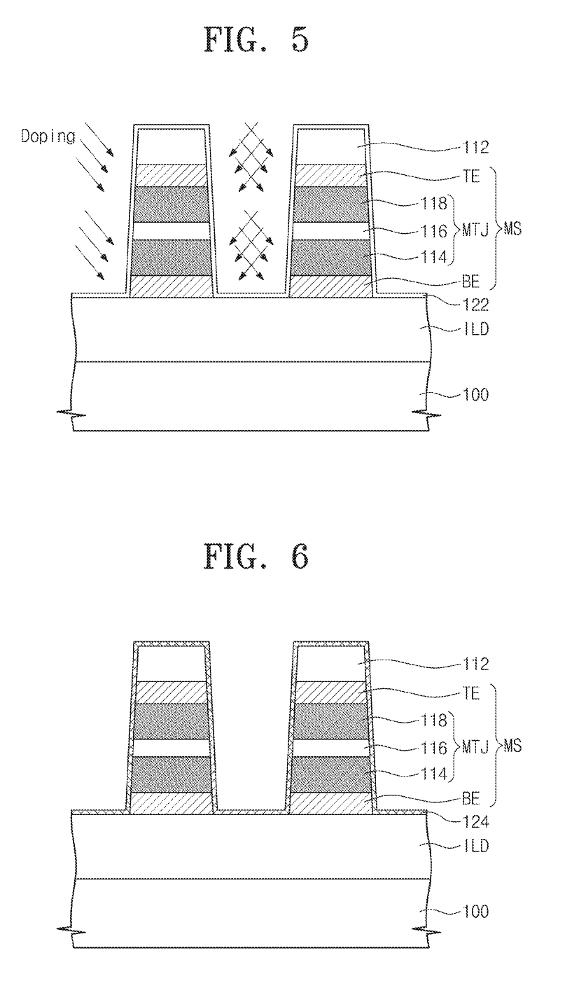

Referring to FIG. 5 and operation 903 in FIG. 9, a material layer 122 may be formed on the sidewalls of the magnetic tunnel junction structures MS on which the etch by-products 120 may be attached by doping the magnetic tunnel junction structures MS with oxidation-facilitation dopants. The oxidation-facilitation dopants may include boron (B) and/or carbon (C). The doping process of the oxidation-facilitation dopants may include performing a plasma doping process with the oxidation-facilitation dopants on the sidewalls of the magnetic tunnel junction structures MS on which the etch by-products 120 may be attached. For example, the plasma doping process may be performed using a plasma in an in-situ manner after the etching the magnetic structure MS using a plasma. In other example embodiments, the doping process of the oxidation-facilitation dopants may be performed using an ion-implantation process of implanting the oxidation-facilitation dopants on the sidewalls of the magnetic tunnel junction structures MS on which the etch by-products may be attached.

As an example embodiment, the etch by-products 120 may have a random thickness and/or random configuration, and the oxidation-facilitation dopants may be evenly distributed in the etch by-products 120. The material layer 122 may be formed to be continuous on the substrate 100 on which the magnetic tunnel junction structures MS have been formed, as depicted in the drawings, but such may not always be the case.

In some example embodiments, the oxidation-facilitation dopants may be chemically or physically combined with the etch by-products 120. For example, the etch by-products 120 may include at least one metal that is contained in the first magnetic pattern 114 and/or the second magnetic pattern 118 such that the oxidation-facilitation dopants may chemically and/or physically combine with the metal to form a chemical compound thereof and/or a physical mixture thereof. The material layer 122 may include the etch by-products 120 that include a metal, such as Pt, Pd, Co, Mg, Fe, a precious metal other than palladium (Pd), and at least one of boron (B), carbon (C), a boron-based metal compound (or a compound of boron and at least one metal contained in the etch by-products, (e.g., PtₓB_{y}, PdₓB_{y}, CoₓB_{y}, MgₓB_{y}, and/or FeₓB_{y})), and carbon-based metal compound (or a compound of carbon and at least one metal contained in the etch by-products, e.g., PtₓC_{y}, PdₓC_{y}, CoₓC_{y}, MgₓC_{y}, and/or FeₓC_{y})).

Referring to FIG. 6 and operation 904 in FIG. 9, the material layer 122 may be changed or transformed into an oxide layer 124 through an oxidation process. During the oxidation process, the material layer 122 may actively react with oxygen because the material layer 122 includes the etch by-products 120 that include at least one metal contained the first and second magnetic patterns 114 and 116 (e.g., Pt, Pd, Co, Mg and/or Fe) and the oxidation-facilitation dopants. For example, the oxide layer 124 may include a compound of the etch by-products 120 and oxygen (e.g., oxide of at least one metal contained in the first and second magnetic patterns 114 and/or 118), and a compound of oxygen and the oxidation-facilitation dopants. The compound of oxygen and the oxidation-facilitation dopants may include at least one of boron oxide (BₓO_{y}), carbon oxide (CₓO_{y}), an oxide of a compound of at least one metal contained in the first and/or second magnetic patterns 114 and 118 combined with boron, and an oxide of a compound of at least one metal contained in the first and/or second magnetic patterns 114 and 118 combined with carbon.

In some example embodiments, the oxidation process may include a radical oxidation process. In some embodiments, the oxidation process is performed by flowing oxygen on the material layer 122 at temperature ranging from about 0° C. to about 500° C. in an in-situ manner in a same process chamber after forming the material layer 122. In other example embodiments, the oxidation process may be performed using oxygen contained in the insulating layer ILD as an oxygen source. Hereinafter, the oxidation process will be described in detail with reference to FIG. 8.

FIG. 8 is a cross-sectional view depicting an oxidation process of the magnetic tunnel junction structure according to example embodiments of the inventive concepts.

Referring to FIG. 8, the insulating layer ILD may include an oxide such that oxygen contained in the insulating layer ILD may be used as an oxygen source. For example, oxygen ions (O⁺, O₂⁺) may be obtained from the insulating layer ILD by a sputtering process using an inert gas, such as argon (Ar).

When the material layer 122 (FIG. 6) is changed or transformed into the oxide layer 124, since the etch by-products 120 including the metal and the oxidation-facilitation dopants have a high oxygen affinity, the oxide layer 124 with a desired thickness may be formed, although a processing time of the oxidation process may be short. Further, since the materials having the oxygen affinity are formed on surfaces of the magnetic tunnel junction structures MS, oxygen may not penetrate into the magnetic tunnel junction structures MS. Accordingly, the oxide layer 124 formed on the sidewalls of the magnetic tunnel junction structures MS may be thinned. As the oxide layer 124 on the sidewalls of the magnetic tunnel junction structures MS has a relatively thin thickness, a linear width of each of magnetic tunnel junction structures MS may not significantly increase.

A thickness or configuration of the material layer 122 may be random, and oxygen in the material layer 122 may evenly combine with the oxidation-facilitation dopants to form the oxide layer 124 having a substantially uniform thickness. Accordingly, deterioration of the magnetic memory device by the oxidation process may be reduced or prevented.

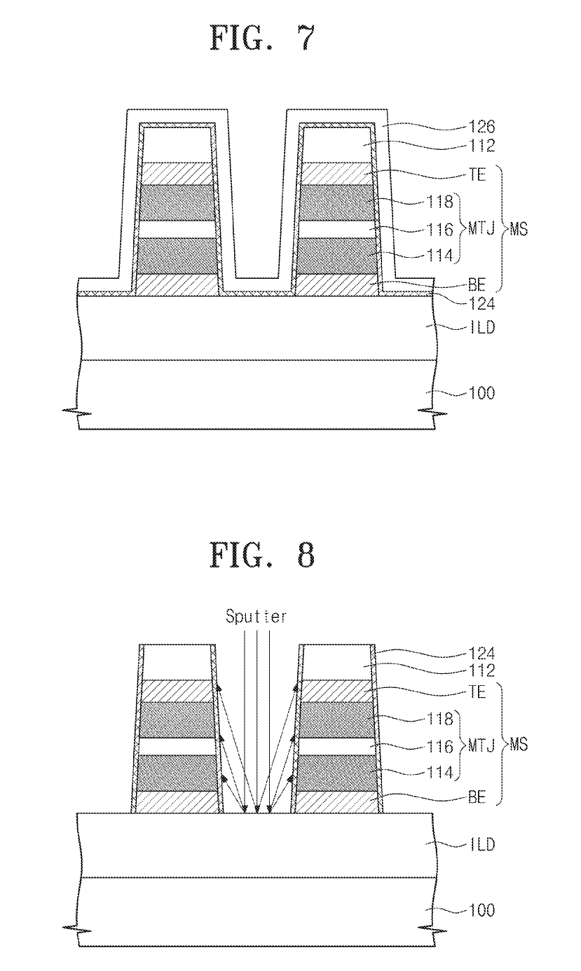

Referring back to FIG. 7 and operation 905 in FIG. 9, a capping layer 126 may be conformally formed on the oxide layer 124 to cover the magnetic tunnel junction structures MS. The capping layer 126 may be formed on the mask pattern 112. The capping layer 126 may include an insulating material, such as silicon oxide, silicon nitride, silicon oxynitride, or aluminum oxide.

When a thermal treatment process (e.g., an interconnection process) is subsequently performed at a high temperature, materials contained in the capping layer 126 may move.

However, the oxide layer 124 may prevent the material in the capping layer 126 from migrating into the magnetic tunnel junction structures MS. In this case, the oxide layer 124 may further include materials formed by a chemical or physical combination of the materials in the oxide layer 124 and the materials in the capping layer 126.

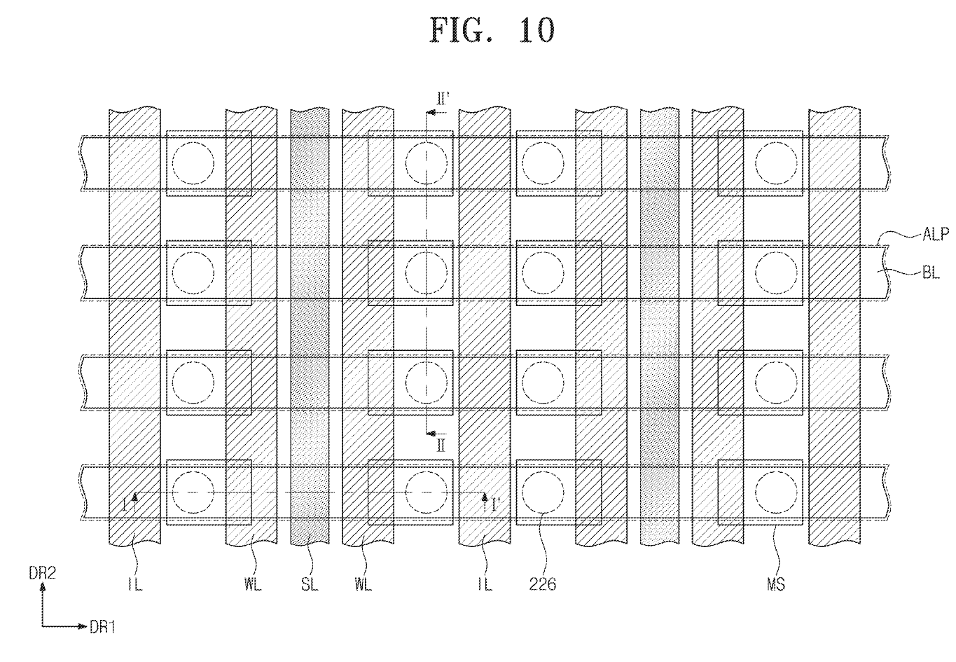

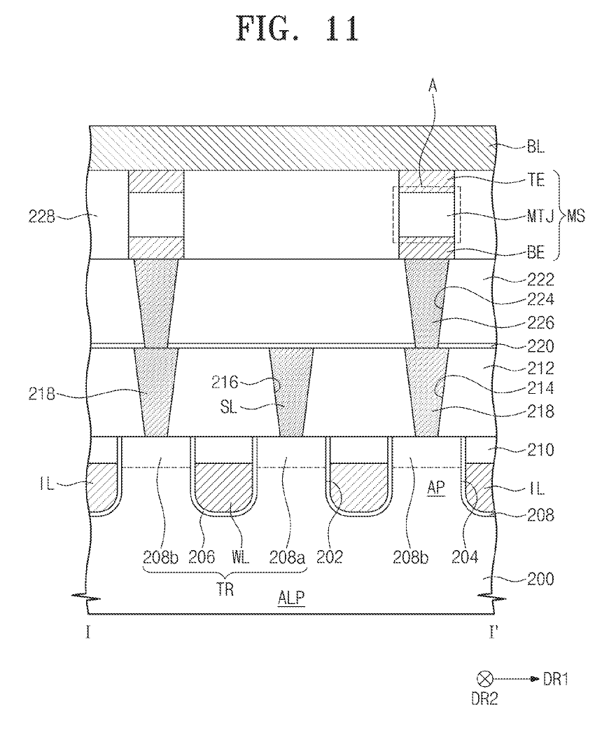

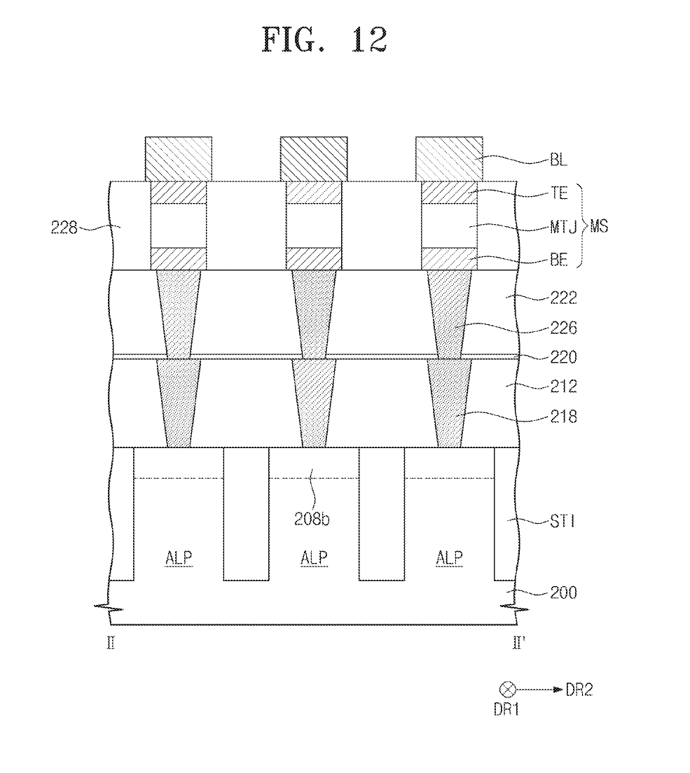

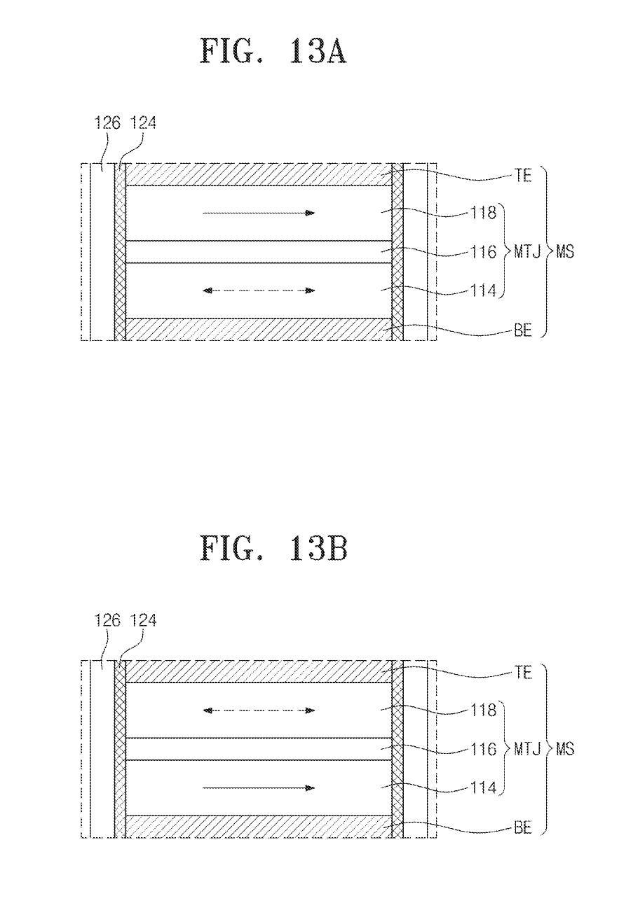

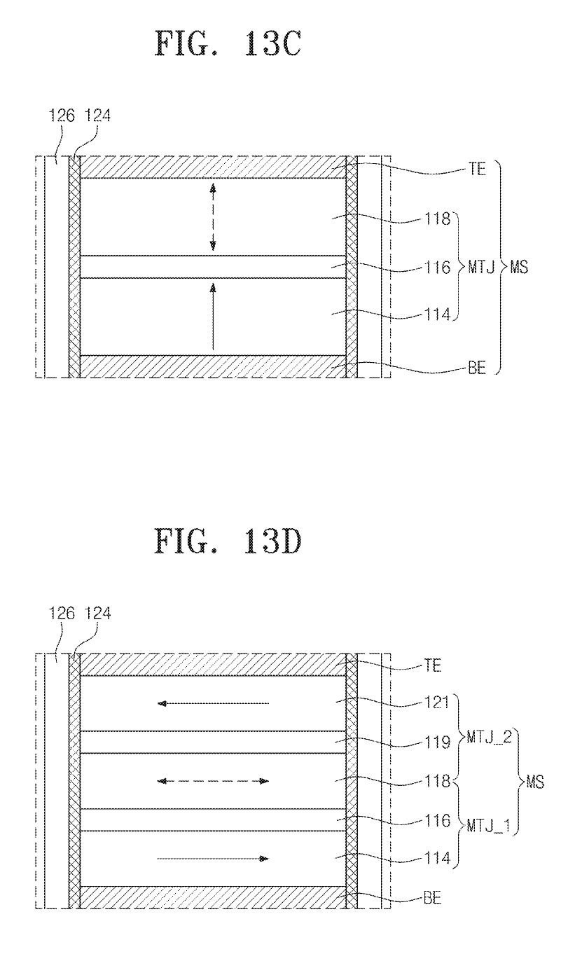

FIG. 10 is a plan view depicting a semiconductor device according to example embodiments of the inventive concepts. FIG. 11 is a cross-sectional view taken along line I-I′ of FIG. 10, and FIG. 12 is a cross-sectional view taken along line II-II′ of FIG. 10. FIGS. 13A through 13D are respectively enlarged cross-sectional views depicting a magnetic tunnel junction structure according to example embodiments of the inventive concepts.

Referring to FIGS. 10 through 12, a semiconductor device may include a substrate 200 that has device isolation patterns STI formed in the substrate 200, transistors TR (e.g., selection devices), isolation lines IL, first contact plugs 218, source lines SL, second contact plugs 226, magnetic tunnel junction structures MS (e.g., memory elements) and bit lines BL. The semiconductor device may be a magnetic memory device.

The substrate 200 may be a semiconductor substrate, such as a silicon substrate, a germanium substrate or silicon-germanium substrate. The device isolation patterns STI may define active line patterns ALP that extend in first direction DR1.

Gate recess regions 202 and isolation recess regions 204 may be disposed in the substrate 200 and may extend in a second direction DR2 that crosses the first direction DR1 in substantially a perpendicular direction.

The isolation recess regions 204 may cross the active line patterns ALP and the device isolation patterns STI, and may have a groove shape. The isolation recess regions 204 may be evenly arranged to extend parallel or substantially parallel to the second direction DR2 in a plan view. The isolation recess regions 204 may divide the active line patterns ALP into active patterns AP. Each of the active patterns AP may correspond to a portion of each of the active line patterns ALP and may be disposed between adjacent isolation recess regions 204. For example, each of the active patterns AP may be defined or delimited by adjacent device isolation patterns STI and adjacent isolation recess regions 204. The active patterns AP may be arranged in a matrix along the first and second directions DR1 and DR2.

The gate recess regions 202 may cross the active patterns AP that are arranged along the second direction DR2. The gate recess regions 202 may extend parallel or substantially parallel to the isolation recess regions 204 and may have a groove shape. As an example embodiment, a pair of the gate recess regions 204 may cross respective active patterns AP and may be disposed between a pair of the isolation recess regions 204. In this case, a pair of the transistors TR may be formed on the respective active patterns AP.

A depth of each of the gate recess regions 202 may be substantially equal to a depth of each of the isolation recess regions 204. In one embodiment, when measured in the first direction DR1, a width of each of the gate recess regions 202 may be substantially equal to a width of each of the isolation recess regions 204. In another embodiment, a width of each of the gate recess regions 202 in the first direction DR1 may be different from the width of each of the isolation recess regions 204.

The depth of each of the gate recess regions 202 and the depth of each of the isolation recess regions 204 may be less than a depth of each of the device isolation patterns STI.

The transistors TR may each include a cell gate insulating layer 206, a word line WL, a first impurity region 208a and a second impurity region 208b. For example, the transistors TR may function as a selection device for the semiconductor device (e.g., the magnetic memory device). The word line WL may fill a lower portion of each of the gate recess regions 202. The word line WL may extend linearly in substantially the second direction DR2. The cell gate insulating layer 206 may be disposed in each of the gate recess regions 202 and may be interposed between the word line WL and the substrate 200. The first impurity region 208a may be disposed in each of the active patterns AP between adjacent word lines WL. The second impurity region 208b may be disposed in each of the active patterns AP between the word line WL and the isolation line SL. In an example embodiment, the first impurity region 208a may be disposed in a central region in each of the active patterns AP, and a pair of the second impurity regions 208b may be disposed in edge regions of each of the active patterns AP. A pair of the transistors TR formed in each of the active patterns AP may share the first impurity region 208a. The first and second impurity regions 208a and 208b may correspond to source/drain regions of the transistor TR. For example, the first impurity region 208a may be a source region and the second impurity region may be a drain region 208b. However, the example embodiments of the inventive concepts are not limited thereto.

Each of the isolation lines IL may fill a lower portion of each of the isolation recess regions 204. Each of the isolation lines IL may extend linearly in substantially the second direction DR2. The semiconductor device may further include an isolation gate insulating layer 208 that may be disposed in each of the isolation recess regions 204 and may be interposed between each of the isolation lines IL and the substrate 200.

The semiconductor device may further include gate mask patterns 210 on the word lines WL. The gate mask patterns 210 may respectively fill upper portions of the gate recess regions 202 having the word lines WL therein and upper portions of the isolation recess regions 204 having the isolation lines IL therein. Top surfaces of the gate mask pattern 210 may be substantially coplanar with a top surface of the substrate 200.

When the semiconductor device operates, an isolation voltage may be applied to the isolation lines IL. The isolation voltage may prevent a formation of channels under the isolation recess regions 204. For example, channel regions under the isolation lines IL may be turned-off by the isolation voltage. Thus, the active patterns AP within an active line pattern ALP may be electrically isolated from one another. For example, when the active line patterns ALP are doped with p-type dopants, the isolation voltage of a ground voltage or a negative voltage may be applied to the isolation lines IL.

Each of the word lines WL may include a semiconductor material that is doped with dopants (e.g., doped silicon), a metal (e.g., tungsten, aluminum, titanium and/or tantalum), a conductive metal nitride (e.g., titanium nitride, tantalum nitride and/or tungsten nitride), and/or a metal-semiconductor compound (e.g., metal silicide). The isolation lines IL may include the same material as the material used for the word lines WL. The cell gate insulating layer 206 and the isolation gate insulating layer 208 may include, for example, silicon oxide, silicon nitride, silicon oxynitride and/or a high-k dielectric material (e.g., an insulating metal oxide, such as hafnium oxide, aluminum oxide or zirconium oxide). The gate mask pattern 210 may include, for example, silicon oxide, silicon nitride and/or silicon oxynitride.

The semiconductor device may further include a first interlayer insulation layer 212. The first interlayer insulation layer 212 may include, for example, silicon oxide. The source lines SL may fill respective source grooves 216 that are formed within the first interlayer insulation layer 212. The source lines SL may each include a semiconductor material that are doped with dopants (e.g., doped silicon), a metal (e.g., tungsten, aluminum, titanium and/or tantalum), a conductive metal nitride (e.g., titanium nitride, tantalum nitride and/or tungsten nitride) and/or a metal-semiconductor compound (e.g., metal silicide). Each of the source lines SL may be electrically connected to a plurality of the first impurity regions 208a that are arranged in substantially the second direction DR2. Additionally, the first contact plugs 218 may be disposed in respective first contact holes 214 within the first interlayer insulation layer 212 and may be electrically connected to respective second impurity regions 208b. The first contact plugs 218 may be formed from the same material as used to form the source lines SL. The source lines SL and the first contact plugs 218 may have top surfaces that are substantially coplanar with a top surface of the first interlayer insulation layer 212.

The semiconductor device may further include an etch-stop layer 220 on the first interlayer insulation layer 212. The etch-stop layer 220 may cover the top surfaces of the source lines SL. The etch-stop layer 220 may include a material having an etch selectivity with respect to the first interlayer insulation layer 212. For example, the first interlayer insulation layer 212 may include silicon oxide, and the etch-stop layer 220 may include silicon nitride and/or silicon oxynitride.

The semiconductor device may further include a second interlayer insulation layer 222 on the etch-stop layer 220. The second interlayer insulation layer 222 may include, for example, silicon oxide.

The second contact plugs 226 may be disposed in respective second contact holes 224 that pass through the second interlayer insulation layer 222 and the etch-stop layer 220. The second contact plugs 226 may be respectively electrically connected to the second impurity regions 208b via a corresponding first contact plug 218. In some example embodiments, an ohmic-contact pattern may be disposed between each of the first contact plugs 218 and each of the second contact via plugs 226, between each of the first contact plugs 218 and each of the second impurity regions 208b and/or between each of the source lines SL and each of the first impurity regions 208a. The ohmic-contact pattern may include a metal-semiconductor compound (e.g., a metal silicide, such as cobalt silicide or titanium silicide).

The magnetic tunnel junction structures MS may be disposed on the second interlayer insulation layer 222. Each of the magnetic tunnel junction structures MS may include a bottom electrode BE, a magnetic tunnel junction MTJ and a top electrode TE. Each of the magnetic tunnel junction structures MS may be configured as one of the structures depicted in FIGS. 13A through 13D. The structures will be described later with reference to FIGS. 13A through 13D.

The magnetic tunnel junction structures MS may respectively be disposed to vertically overlap the second contact plugs 226.

The semiconductor device may further include a third interlayer insulation layer 228 on the second interlayer insulation layer 222 that covers the magnetic tunnel junction structures MS. The third interlayer insulation layer 228 may expose a top surface of each of the magnetic tunnel junction structures MS. The third interlayer insulation layer 228 may include, for example, silicon oxide.

The bit line BL may be disposed on the third interlayer insulation layer 228. The bit line BL may extend substantially in the first direction DR1. The bit line BL may be electrically connected to a plurality of the magnetic tunnel junction structures MS that are arranged substantially in the first direction DR1. In some example embodiments, a contact plug may not be disposed between the bit line BL and each of the magnetic tunnel junction structures MS. Thus, process steps of manufacturing the semiconductor device may be reduced, and a contact resistance between the bit line BL and the magnetic tunnel junction structures MS may also be decreased. Additionally, distribution of the contact resistance between the bit line BL and the magnetic tunnel junction structures MS may be decreased. Hereinafter, a detail description of the magnetic tunnel junction structure MS will be made below.

Referring to FIGS. 13A and 13B, the magnetic tunnel junction structure MS may include a bottom electrode BE, a first magnetic pattern 114, a tunnel barrier pattern 116, a second magnetic pattern 118 and a top electrode TE. Further, the magnetic tunnel junction structure MS may include an oxide layer 124 and a capping layer 126 on surfaces of the bottom electrode BE, the first magnetic pattern 114, the tunnel barrier pattern 116, the second magnetic pattern 118 and the top electrode TE. The oxide layer 124 and the capping layer 126 may be the same as the oxide layer and the capping layer described with reference to FIG. 7.

In the magnetic tunnel junction structure MS of FIGS. 13A and 13B, magnetization directions of the first second magnetic patterns 114 and 118 may be substantially parallel to a top surface of the tunnel barrier pattern 116 such that a horizontal magnetization structure may be formed. That is the first and second magnetic patterns 114 and 118 may form a magnetic tunnel junction structure that has a horizontal magnetic anisotropy.

Referring to FIG. 13A, the first magnetic pattern 114 may act as a pinned magnetic layer, and the second magnetic pattern 118 may act as a free magnetic layer. Referring to FIG. 13B, the first magnetic pattern 114 may act as the free magnetic layer, and the second magnetic pattern 118 may act as the pinned magnetic layer.

A electrical resistance of the magnetic tunnel junction structure MS may be greater when the magnetization directions of the first and second magnetic patterns 114 and 118 are anti-parallel to one another (i.e., in opposite directions from one another) than when the magnetization directions of the first and second magnetic patterns 114 and 118 are parallel to one another (i.e., in the same direction as each other). Thus, the electrical resistance of the magnetic tunnel junction structure MS may be controlled by changing the magnetization direction of the second magnetic pattern 118. For example, the magnetization direction of the second magnetic pattern 118 may be changed by spin torques of electrons in a writing current. Datum may be stored in the magnetic tunnel junction structure MS using a difference in the electrical resistances based on the magnetization direction.

The magnetic tunnel junction structure MS shown in FIGS. 13A and 13B may be the same magnetic tunnel junction structure as described with reference to FIG. 7.

Referring to FIG. 13C, the magnetic tunnel junction structure MS may include a bottom electrode BE, a first magnetic pattern 114, a tunnel barrier pattern 116, a second magnetic pattern 118 and a top electrode TE. Further, the magnetic tunnel junction structure MS may include an oxide layer 124 and a capping layer 126 on surfaces of the bottom electrode BE, the first magnetic pattern 114, the tunnel barrier pattern 116, the second magnetic pattern 118 and the top electrode TE. The oxide layer 124 and the capping layer 126 may be the same as the oxide layer and the capping layer described with reference to FIG. 7.

In the magnetic tunnel junction structure MS of FIG. 13C, magnetization directions of the first and second magnetic patterns 114 and 118 may be substantially perpendicular to a top surface of the tunnel barrier pattern 116 such that a vertical magnetization structure may be formed. That is, the first and second magnetic patterns 114 and 118 may form a magnetic tunnel junction structure MS that has a vertical magnetic anisotropy. The first magnetic pattern 114 may act as the pinned magnetic layer, and the second magnetic pattern 118 may act as the free magnetic layer.

The magnetic tunnel junction structure MS of FIG. 13C may be the same as the magnetic tunnel junction structure described with reference to FIG. 7.

Referring to FIG. 13D, the magnetic tunnel junction structure MS may include a bottom electrode BE, a first magnetic tunnel junction MTJ_1, a second magnetic tunnel junction MTJ_2 and a top electrode TE. Further, the magnetic tunnel junction structure MS may include an oxide layer 124 and a capping layer 126 on surfaces of the bottom electrode BE, the first magnetic tunnel junction MTJ_1, the second magnetic tunnel junction MTJ_2 and the top electrode TE. The oxide layer 124 and the capping layer 126 may be the same as the oxide layer and the capping layer described with reference to FIG. 7.

For example, the magnetic tunnel junction structure MS may include a first magnetic pattern 114, a first tunnel barrier pattern 116, a second magnetic pattern 118, a second barrier pattern 119, and a third magnetic pattern 121 that are sequentially stacked. The first and third magnetic patterns 114 and 121 may act as the pinned magnetic layer, and the second magnetic pattern 118 may act as the free magnetic layer. The first and second tunnel barrier patterns 116 and 119 may have different thicknesses. In this magnetic tunnel junction structure MS, the first magnetic pattern 114, the first tunnel barrier pattern 116 and the second magnetic pattern 118 may form the first magnetic tunnel junction MTJ_1. The second magnetic pattern 118, the second tunnel barrier pattern 119, the third magnetic pattern 121 may form the second magnetic tunnel junction MTJ_2.

The first and third magnetic patterns 114 and 121 may have a magnetization direction that is fixed in a particular direction. However, the magnetization direction of the first magnetic pattern 114 may be opposite to the magnetization direction of the third magnetic pattern 121. The second magnetic pattern 118 may have a magnetization direction that can be switched in parallel or antiparallel to the fixed magnetization direction of the first and second magnetic patterns 114 and 121. The magnetization of the first through third magnetic patterns 114, 118 and 121 may be substantially parallel to top surfaces of the first and second tunnel barrier patterns 116 and 119. In an alternative embodiment, the magnetization of the first through third magnetic patterns 114, 118 and 121 may be substantially perpendicular to the top surfaces of the first and second tunnel barrier patterns 116 and 119.

The first magnetic pattern 114, the first tunnel barrier pattern 116, the second magnetic pattern 118, the second tunnel barrier pattern 119 and the third magnetic pattern 121 may be sequentially stacked between the bottom electrode BE and the top electrode TE.

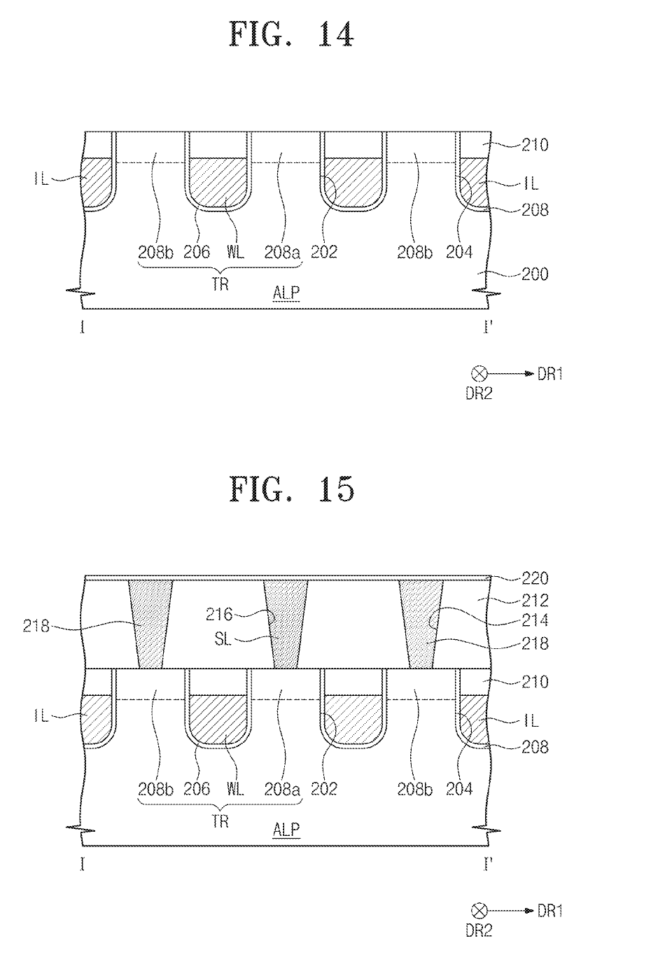

FIGS. 14 through 17 are cross-sectional views depicting a method of manufacturing a semiconductor device according to example embodiments of the inventive concepts. FIGS. 14 through 17 are cross-sectional views taken along line I-I′ of FIG. 10.

Referring to FIGS. 10 and 14, device isolation patterns (STI, FIG. 12) may be formed in a substrate 200 to define active line patterns ALP. Each of the active patterns ALP may extend substantially in a first direction DR1. The substrate 200 may be a semiconductor substrate, such as a silicon substrate, a germanium substrate, or silicon-germanium substrate. The device isolation patterns STI may extend substantially in first direction DR1. The device isolation patterns STI may include, for example, silicon oxide, silicon nitride and/or silicon oxynitride.

The device isolation patterns STI and the active line patterns ALP may be patterned to form gate recess regions 202 and isolation recess regions 204 that extend in a second direction DR2 that crosses the first direction DR1. The gate recess regions 202 and the isolation recess regions 204 may be parallel or substantially parallel to one another. Each of the active line patterns ALP may be divided into a plurality of active patterns AP by the isolation recess regions 202. The gate recess regions 202 may cross the active patterns AP. A depth of each of the gate recess regions 202 and the isolation recess regions 204 may be less than a depth of the device isolation patterns STI.

A cell gate insulating layer 206 may be formed in an inner surface of each of the gate recess regions 202 to have a substantially uniform thickness. An isolation gate insulating layer 208 may be formed in an inner surface of each of the isolation recess regions 204 to have a substantially uniform thickness. As an example embodiment, the cell gate insulating layer 206 and the isolation gate insulating layer 208 may be formed at same time. The cell gate insulating layer 206 and the isolation gate insulating layer 208 may each be a silicon oxide layer that is formed by thermally oxidizing a surface of the substrate 200. In some example embodiments, the cell gate insulating layer 206 and the isolation gate insulating layer 208 may include silicon oxide, silicon nitride, silicon oxynitride and/or a high-k dielectric material (e.g., an insulating metal oxide, such as hafnium oxide, aluminum oxide or zirconium oxide).

Word lines WL and isolation lines IL may be respectively formed in the gate recess regions 202 and the isolation recess regions 204. The word lines WL and isolation lines IL may be formed from a conductive material that fills lower portions of the gate recess regions 202 and the isolation recess regions 204. The conductive material may include a semiconductor material doped with dopants (e.g., doped silicon), a metal (e.g., tungsten, aluminum, titanium and/or tantalum), a conductive metal nitride (e.g., titanium nitride, tantalum nitride and/or tungsten nitride) and/or a metal-semiconductor compound (e.g., metal silicide). The word lines WL and the isolation lines IL may extend in substantially the second direction DR2.

Gate mask patterns 210 may be formed on the word line WL and the isolation lines IL. For example, the gate mask patterns 210 may fill the upper portions of the gate recess regions 202 that contain the word lines WL and the upper portions of the isolation recess regions 202 that contain the isolation lines IL. Each of the gate mask patterns 210 may include silicon oxide, silicon nitride and/or silicon oxynitride.

A first impurity region 208a and a second impurity region 208b may be formed by implanting impurities into the active patterns AP on opposite sides of each of the word lines WL. The first and second impurity regions 208a and 208b may have bottom surfaces that are higher than the bottom surfaces of the word lines WL and the isolation lines IL with respect to a top surface of the substrate 200.

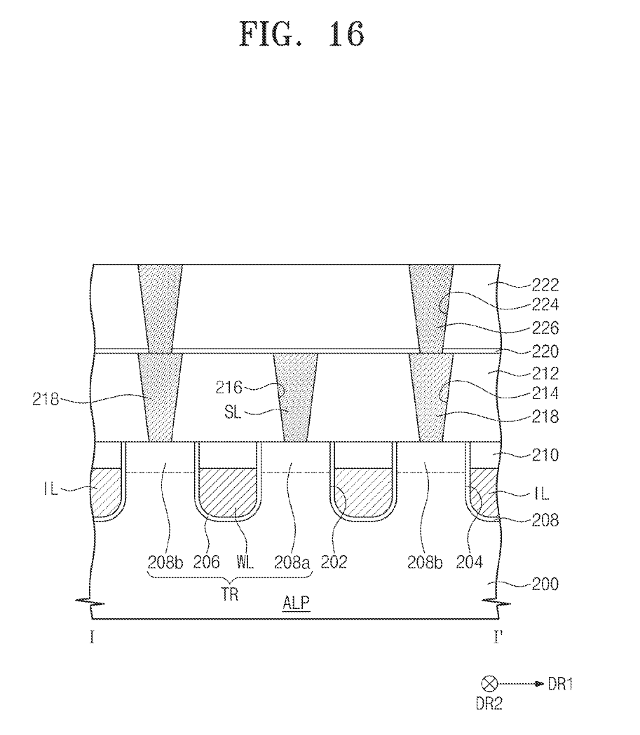

Referring to FIG. 15, a first interlayer insulation layer 212 may be formed on the substrate 200. The first interlayer insulation layer 212 may be formed from silicon oxide. The first interlayer insulation layer 212 may be etched to form first contact holes 214 and source grooves 216. The first contact holes 214 and the source grooves 216 may be filled with a conductive material to form first contact plugs 218 and source lines SL. The conductive material may include a semiconductor material that are doped with dopants (e.g., doped silicon), a metal (e.g., tungsten, aluminum, titanium and/or tantalum), a conductive metal nitride (e.g., titanium nitride, tantalum nitride and/or tungsten nitride) and/or a metal-semiconductor compound (e.g., metal silicide). The first contact plugs 218 may contact the second impurity regions 208b, and the source lines SL may contact the first impurity regions 208a.

In some example embodiments, an ohmic-contact pattern may be disposed between each of the source lines SL and each of the first impurity regions 208a, and/or between each of the first contact plugs 218 and each of the second impurity regions 208b. The ohmic-contact pattern may include a metal-semiconductor compound (e.g., a metal silicide, such as cobalt silicide or titanium silicide).

An etch-stop layer 220 may be formed on the first interlayer insulation layer 212. The etch-stop layer 220 may include a material having an etch selectivity with respect to the first interlayer insulation layer 212, the source lines SL and the first contact plugs 218. For example, the etch-stop layer 220 may be formed from silicon nitride and/or silicon oxynitride.

Referring to FIG. 16, a second interlayer insulation layer 222 may be formed on the etch-stop layer 220. The second interlayer insulation layer 222 may include, for example, silicon oxide. The second interlayer insulation layer 222 and the etch-stop layer 220 may be etched to form second contact holes 224. The second contact holes 224 may be filled with a conductive material to form second contact plugs 226. The conductive material may include a semiconductor material that are doped with dopants (e.g., doped silicon), a metal (e.g., tungsten, aluminum, titanium and/or tantalum), a conductive metal nitride (e.g., titanium nitride, tantalum nitride and/or tungsten nitride) and/or a metal-semiconductor compound (e.g., metal silicide).

The second contact plugs 226 may respectively be in contact with the first contact plugs 218 to be electrically connected to the respective second impurity regions 208b. In some example embodiments, an ohmic-contact pattern may be disposed between each of the first contact plugs 218 and each of the second contact via plugs 226. The ohmic-contact pattern may include a metal-semiconductor compound (e.g., a metal silicide, such as cobalt silicide or titanium silicide).

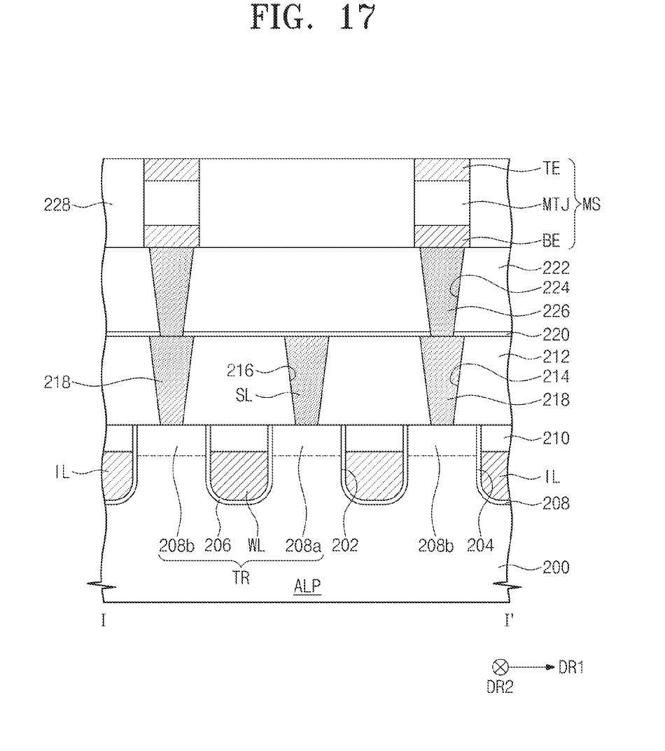

Referring to FIGS. 10 and 17, a plurality of magnetic tunnel junction structures MS may be formed on the second interlayer insulation layer 222. Each of the magnetic tunnel junction structures MS may include a bottom electrode, a magnetic tunnel junction, MTJ and a top electrode. Each of the magnetic tunnel junction structures MS may be formed using manufacturing techniques described with reference to FIGS. 3 through 8. Each of the magnetic tunnel junction structures MS may be patterned in an island-type shape that is separated from one another in the first and second directions DR1 and DR2. The magnetic tunnel junction structures MS may respectively vertically overlap the second contact plugs 226.

Referring again to FIGS. 10 and 11, a third interlayer insulation layer 228 may be formed on the second interlayer insulation layer 222 to cover the magnetic tunnel junction structures MS. The third interlayer insulation layer 228 may expose a top surface of each of the magnetic tunnel junction structures MS. The third interlayer insulation layer 228 may include silicon oxide.

A bit line BL that extends in substantially the first direction DR1 may be formed on the third interlayer insulation layer 228. The bit line BL may be electrically connected to a plurality of the magnetic tunnel junction structures MS that are arranged in substantially the first direction DR1.

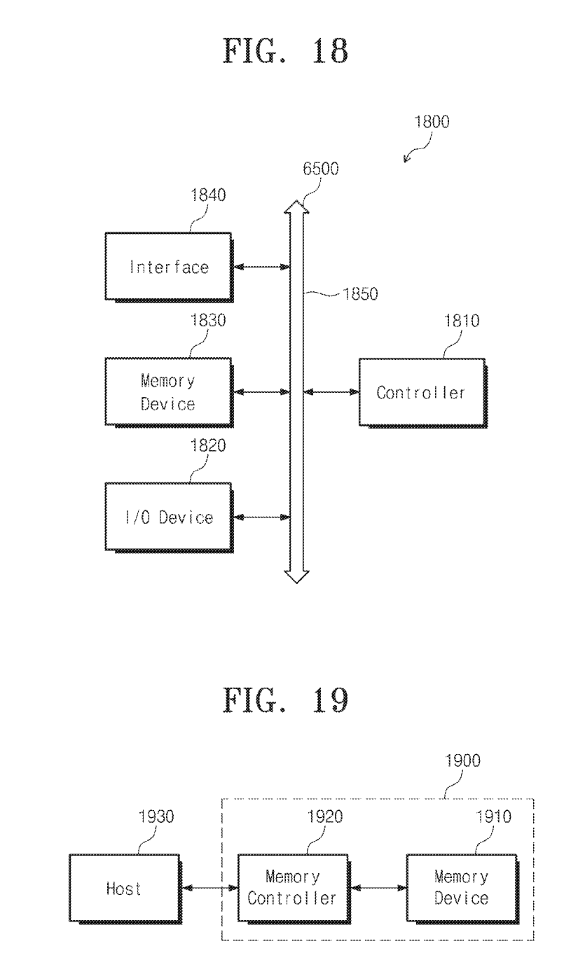

FIG. 18 depicts an electronic device 1800 that comprises one or more integrated circuits (chips) comprising a semiconductor device that includes a magnetic tunnel junction device according to embodiments disclosed herein. Electronic device 1800 may be used in, but not limited to, a computing device, a personal digital assistant (PDA), a laptop computer, a mobile computer, a web tablet, a wireless phone, a cell phone, a smart phone, a digital music player, or a wireline or wireless electronic device. The electronic device 1800 may comprise a controller 1810, an input/output device 1820 such as, but not limited to, a keypad, a keyboard, a display, or a touch-screen display, a memory 1830, and a wireless interface 1840 that are coupled to each other through a bus 1850. The controller 1810 may comprise, for example, at least one microprocessor, at least one digital signal process, at least one microcontroller, or the like. The memory 1830 may be configured to store a command code to be used by the controller 1810 or a user data. Electronic device 1800 and the various system components comprising a semiconductor device that includes a magnetic tunnel junction device according to embodiments disclosed herein. The electronic device 1800 may use a wireless interface 1840 configured to transmit data to or receive data from a wireless communication network using a RF signal. The wireless interface 1840 may include, for example, an antenna, a wireless transceiver and so on. The electronic device 1800 may be used in a communication interface protocol of a communication system, such as, but not limited to, Code Division Multiple Access (CDMA), Global System for Mobile Communications (GSM), North American Digital Communications (NADC), Extended Time Division Multiple Access (E-TDMA), Wideband CDMA (WCDMA), CDMA2000, Wi-Fi, Municipal Wi-Fi (Muni Wi-Fi), Bluetooth, Digital Enhanced Cordless Telecommunications (DECT), Wireless Universal Serial Bus (Wireless USB), Fast low-latency access with seamless handoff Orthogonal Frequency Division Multiplexing (Flash-OFDM), IEEE 802.20, General Packet Radio Service (GPRS), iBurst, Wireless Broadband (WiBro), WiMAX, WiMAX-Advanced, Universal Mobile Telecommunication Service—Time Division Duplex (UMTS-TDD), High Speed Packet Access (HSPA), Evolution Data Optimized (EVDO), Long Term Evolution—Advanced (LTE-Advanced), Multichannel Multipoint Distribution Service (MMDS), and so forth.

FIG. 19 depicts a memory system 1900 that may comprise one or more integrated circuits (chips) comprising a semiconductor device that includes an MRAM according to embodiments disclosed herein. The memory system 1900 may comprise a memory device 1910 for storing large amounts of data and a memory controller 1920. The memory controller 1920 controls the memory device 1910 to read data stored in the memory device 1910 or to write data into the memory device 1910 in response to a read/write request of a host 1930. The memory controller 1920 may include an address-mapping table for mapping an address provided from the host 1930 (e.g., a mobile device or a computer system) into a physical address of the memory device 1910. The memory device 1910 may comprise one or more semiconductor devices a semiconductor device that includes a magnetic tunnel junction device according to embodiments disclosed herein.

While example embodiments of the inventive concepts have been particularly shown and described, it will be understood by one of ordinary skill in the art that variations in form and detail may be made therein without departing from the spirit and scope of the attached claims.

1. A method of manufacturing a semiconductor device, the method comprising:
sequentially forming a first magnetic layer, a tunnel barrier layer and a second magnetic layer on a substrate;
forming a magnetic tunnel junction structure by etching the second magnetic layer, the tunnel barrier layer, and the first magnetic layer, the magnetic tunnel junction structure including a first magnetic pattern, a tunnel barrier pattern, and a second magnetic pattern that are sequentially stacked,
forming a material layer that includes oxidation-facilitation dopants on a sidewall of the magnetic tunnel junction structure; and
oxidizing the material layer to form an oxide layer.

2. The method of claim 1, wherein the oxidation-facilitation dopants include boron and/or carbon.

3. The method of claim 1, wherein the material layer further comprises etch by-products attached on the sidewall of the magnetic tunnel junction structure while the second magnetic layer, the tunnel barrier layer, and the first magnetic layer are etched.

4. The method of claim 3, wherein the etch by-products include at least one metal contained in the first and/or second magnetic patterns.

5. The method of claim 4, wherein the material layer includes the at least one metal contained in the first and/or second magnetic patterns, and at least one of boron, carbon, a compound of boron and the at least one metal contained in the first and/or second magnetic patterns, and a compound of carbon and the at least one metal contained in the first and/or second magnetic patterns.

6. The method of claim 3, wherein forming the material layer including the oxidation-facilitation dopants includes implanting the oxidation-facilitation dopants into the magnetic tunnel junction structure having the etch by-products on the sidewall thereof.

7. The method of claim 3, wherein forming the material layer including the oxidation-facilitation dopants includes performing a plasma doping process with the oxidation-facilitation dopants on the magnetic tunnel junction structure having the etch by-products on the sidewall thereof.

8. The method of claim 4, wherein the oxide layer includes oxide of the at least one metal contained in the first and/or second magnetic patterns.

9. The method of claim 8, wherein the oxide layer further includes at least one of a boron oxide, a carbon oxide, an oxide of the at least one metal combined with boron, and an oxide of the at least one metal combined with carbon.

10. The method of claim 1, further comprising conformally forming a capping layer on the oxide layer to cover the magnetic tunnel junction structure.

11. The method of claim 10, further comprising performing a thermal treatment process after forming the capping layer.

12. The method of claim 1, wherein oxidizing the material layer includes performing a radical oxidation process on the material layer or flowing oxygen on the material layer at temperature of 0° C. to 500° C.

13. The method of claim 1, further comprising forming an insulating layer between the substrate and the first magnetic layer,
wherein oxidizing the material layer includes sputtering the insulating layer.

14-17. (canceled)

18. A method of manufacturing a semiconductor device, the method comprising:
forming a magnetic tunnel junction structure including a bottom electrode, a top electrode, and a magnetic tunnel junction between the bottom electrode and the top electrode, the magnetic tunnel junction including a first magnetic pattern, a second magnetic pattern, and a magnetic tunnel barrier pattern between the first magnetic pattern and the second magnetic pattern; and
forming an oxide layer on a sidewall of the magnetic tunnel junction structure, the oxide layer including oxygen, a metal, and at least one of boron and carbon.

19. The method of claim 18, wherein the metal comprises at least one metal contained in the first and/or second magnetic patterns.

20. The method of claim 18, further comprising forming a capping layer on the oxide layer.

21-23. (canceled)

24. A method of manufacturing a semiconductor device, the method comprising:
forming a magnetic tunnel junction structure on a surface of a substrate, the magnetic tunnel junction structure comprising a bottom electrode layer, a first magnetic layer, a tunnel barrier layer, a second magnetic layer, and a top electrode layer sequentially formed on the surface of the substrate;
etching the magnetic tunnel junction structure to form at least one magnetic tunnel junction device, the at least one magnetic tunnel junction device comprising a sidewall surface on which an etching by-product is attached; and
forming an oxide layer from the etching by-product.

25. The method of claim 24, wherein the oxide comprises oxygen, a metal and at least one of boron and carbon.

26. The method of claim 25, wherein at least one of the first magnetic layer and the second magnetic layer comprises the metal.

27. The method of claim 25, wherein forming the oxide layer comprises implanting the at least one of boron and carbon into the etching by-product.

28-34. (canceled)
